(19) United States
(12) Patent Application Publication
(10) Pub. No.: US 2026/0211337 A1
(43) Pub. Date: Jul. 23, 2026

(54) SUBSTRATES FOR CALIBRATION OF A LITHOGRAPHIC APPARATUS

(71) Applicant: ASML NETHERLANDS B.V., Veldhoven (NL)

(72) Inventors: Richard Johannes Franciscus VAN HAREN, Veldhoven (NL); Ronald Henricus Johannes OTTEN, Rosmalen (NL); Suwen LI, Hegelsom (NL); Leon Paul VAN DIJK, Eindhoven (NL)

(73) Assignee: ASML NETHERLANDS B.V., Veldhoven (NL)

(21) Appl. No.: 19/139,170

(22) PCT Filed: Dec. 8, 2023
(86) PCT No.: PCT/EP2023/084925

§ 371 Date: Jun. 13, 2025

(30) Foreign Application Priority Data
Jan. 9, 2023 (EP) 23150716.1

(51) Int. Cl. G03F 7/00

(52) U.S. Cl. CPC G03F 7/70516; G03F 7/705; G03F 7/70633; G03F 7/70775

(57) ABSTRACT

A method of calibrating a lithographic apparatus, the method including: obtaining a substrate having a Young's modulus which is substantially invariant to the orientation of an axis within the plane of the substrate along which the Young's modulus is defined and being provided with reference features; clamping the substrate to a substrate table of the lithographic apparatus; providing patterned features to the clamped substrate using the lithographic apparatus, each patterned feature being provided in proximity to a corresponding reference feature; measuring the position of each patterned feature relative to its corresponding reference feature; and calibrating a grid associated with positioning of substrates by the lithographic apparatus based on the measured positions of the patterned features.

### CROSS-REFERENCE TO RELATED APPLICATIONS

This application claims priority of EP application 23150716.1 which was filed on 9 Jan. 2023, and which is incorporated herein in its entirety by reference.

### FIELD

The present invention relates to substrates and methods for manufacturing substrates configured for calibration of lithographic apparatuses. Further the present invention relates to calibration of lithographic apparatuses to reduce positional errors made during patterning operations of the lithographic apparatus.

### BACKGROUND

A lithographic apparatus is a machine constructed to apply a desired pattern onto a substrate. A lithographic apparatus can be used, for example, in the manufacture of integrated circuits (ICs). A lithographic apparatus may, for example, project a pattern (also often referred to as “design layout” or “design”) at a patterning device (e.g., a mask) onto a layer of radiation-sensitive material (resist) provided on a substrate (e.g., a wafer).

To project a pattern on a substrate a lithographic apparatus may use electromagnetic radiation. The wavelength of this radiation determines the minimum size of features which can be formed on the substrate. Typical wavelengths currently in use are 365 nm (i-line), 248 nm deep ultraviolet (DUV), 193 nm deep ultraviolet (DUV) and 13.5 nm. A lithographic apparatus, which uses extreme ultraviolet (EUV) radiation, having a wavelength within the range 4-20 nm, for example 6.7 nm or 13.5 nm, may be used to form smaller features on a substrate than a DUV lithographic apparatus which uses, for example, radiation with a wavelength of 193 nm.

Low-k₁ lithography may be used to process features with dimensions smaller than the classical resolution limit of a lithographic apparatus. In such process, the resolution formula may be expressed as CD=k₁×λ/NA, where λ is the wavelength of radiation employed, NA is the numerical aperture of the projection optics in the lithographic apparatus, CD is the “critical dimension” (generally the smallest feature size printed, but in this case half-pitch) and k₁ is an empirical resolution factor. In general, the smaller k₁ the more difficult it becomes to reproduce the pattern on the substrate that resembles the shape and dimensions planned by a circuit designer in order to achieve particular electrical functionality and performance. To overcome these difficulties, sophisticated fine-tuning steps may be applied to the lithographic apparatus and/or design layout. These include, for example, but not limited to, optimization of NA, customized illumination schemes, use of phase shifting patterning devices, various optimization of the design layout such as optical proximity correction (OPC, sometimes also referred to as “optical and process correction”) in the design layout, or other methods generally defined as “resolution enhancement techniques” (RET). Alternatively, tight control loops for controlling a stability of the lithographic apparatus may be used to improve reproduction of the pattern at low k₁.

An example of such a control loop is so-called baseline control of the lithographic apparatus. Baseline control is implemented to correct drifts of measurement and actuating components within the lithographic apparatus and consequently keep operation of the lithographic apparatus stable in time. To implement baseline control it is often required to periodically perform reference exposures on so-called reference substrates. The reference substrates are normally from the same material as regular production wafers which are often from (110) or (100) crystalline silicon. The reference wafers are provided with reference features which are normally etched into the reference substrate during dedicated reference substrate manufacturing steps. During the reference exposure the lithographic apparatus patterns a photoresist layer applied to the reference substrate to form patterned features. Subsequently the positional deviations between the patterned features and the reference features are measured, for example using an overlay measurement metrology tool. Based on these measured deviations the lithographic apparatus is calibrated.

However during the clamping of current state of the art reference substrates to a substrate table of the lithographic apparatus undesired non-uniform and asymmetric In-Plane Deformations (IPD) of the reference substrate may be introduced. These non-uniform and often asymmetric deformations may reduce accuracy of the calibration procedure as part of the IPD may then be erroneously attributed to the drift of the lithographic apparatus.

### SUMMARY

It is desirable to provide a substrate and a method of manufacturing a substrate for calibration of the lithographic apparatus which reduces the problem of non-uniform and/or asymmetric IPD of the substrate when clamping said substrate to the substrate table.

It is further desirable to provide a method of calibrating the lithographic apparatus which reduces the problem of non-uniform IPD of the substrate when clamping said substrate to the substrate table.

In a first aspect there is provided a substrate for calibration of a lithographic apparatus, the substrate being characterized in that it has a Young's modulus which is substantially invariant to the orientation of an axis within the plane of the substrate along which said Young's modulus is defined.

In a second aspect there is provided a method of manufacturing a substrate for calibration of a lithographic apparatus, the method comprising; obtaining a substrate made from (1 1 1) oriented silicon; and using a process of Reactive Ion Etching (RIE) to provide reference features to the substrate.

In a third aspect a method of calibrating a lithographic apparatus is provided, the method comprising the following steps: obtaining a substrate being provided with reference features and having a Young's modulus which is substantially invariant to the orientation of an axis within the plane of the substrate along which said Young's modulus is defined; clamping the substrate to a substrate table of the lithographic apparatus; providing patterned features to the clamped substrate using said lithographic apparatus, each patterned feature being provided in proximity to a corresponding reference feature; measuring the position of each patterned feature relative to its corresponding reference feature; and calibrating a grid associated with positioning of substrates by the lithographic apparatus based on the measured positions of the patterned features.

By using a substrate made from a material that has no dependency of its Young's modulus to its orientation (with respect to the substrate table), such as (111) oriented crystalline silicon, clamping forces exerted to the substrate will give a more uniform and to a large extend radially symmetric IPD.

The more uniform and symmetric IPD will be visible in the overlay measurements used for the calibration of the lithographic apparatus, but are better correctable and easier to model than the less uniform and less symmetric IPD contribution to overlay associated with state of the art reference substrates made from (110) or (001) silicon.

### BRIEF DESCRIPTION OF THE DRAWINGS

Embodiments of the invention will now be described, by way of example only, with reference to the accompanying schematic drawings, in which:

FIG. 1 depicts a schematic overview of a lithographic apparatus;

FIG. 2 depicts a schematic overview of a lithographic cell;

FIG. 3 depicts a schematic representation of holistic lithography, representing a cooperation between three key technologies to optimize semiconductor manufacturing;

FIG. 4 is a schematic overview of control mechanisms in a lithographic process utilizing a stability module;

FIG. 5 is a plot of the angular dependency of Young's modulus for three crystal orientations of silicon.

FIGS. 6a and 6b depict a first and a second substrate loading sequence.

FIGS. 7a and 7b demonstrate geometric integrity of reference features applied to a reference substrate according to an embodiment of the invention.

FIGS. 8a and 8b demonstrate an observed improvement in a measured overlay fingerprint by using a reference substrate according to an embodiment of the invention.

### DETAILED DESCRIPTION

In the present document, the terms “radiation” and “beam” are used to encompass all types of electromagnetic radiation, including ultraviolet radiation (e.g. with a wavelength of 365, 248, 193, 157 or 126 nm) and EUV (extreme ultra-violet radiation, e.g. having a wavelength in the range of about 5-100 nm).

The term “reticle”, “mask” or “patterning device” as employed in this text may be broadly interpreted as referring to a generic patterning device that can be used to endow an incoming radiation beam with a patterned cross-section, corresponding to a pattern that is to be created in a target portion of the substrate. The term “light valve” can also be used in this context. Besides the classic mask (transmissive or reflective, binary, phase-shifting, hybrid, etc.), examples of other such patterning devices include a programmable mirror array and a programmable LCD array.

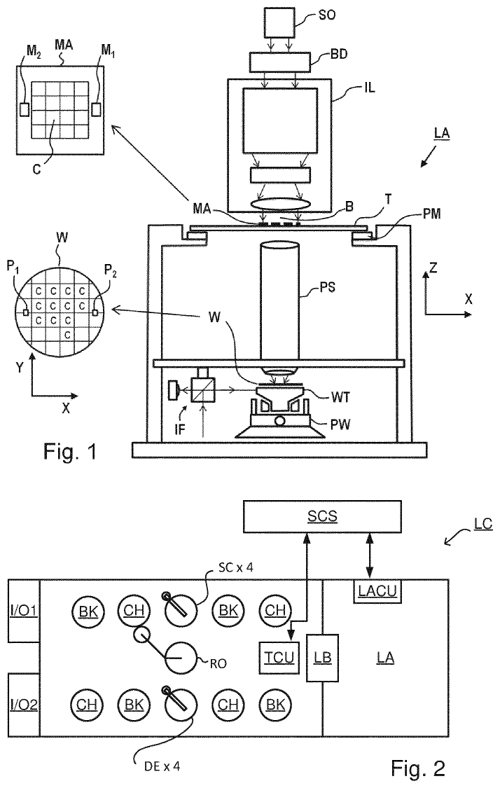

FIG. 1 schematically depicts a lithographic apparatus LA. The lithographic apparatus LA includes an illumination system (also referred to as illuminator) IL configured to condition a radiation beam B (e.g., UV radiation, DUV radiation or EUV radiation), a mask support (e.g., a mask table) MT constructed to support a patterning device (e.g., a mask) MA and connected to a first positioner PM configured to accurately position the patterning device MA in accordance with certain parameters, a substrate support (e.g., a wafer table) WT constructed to hold a substrate (e.g., a resist coated wafer) W and connected to a second positioner PW configured to accurately position the substrate support in accordance with certain parameters, and a projection system (e.g., a refractive projection lens system) PS configured to project a pattern imparted to the radiation beam B by patterning device MA onto a target portion C (e.g., comprising one or more dies) of the substrate W.

In operation, the illumination system IL receives a radiation beam from a radiation source SO, e.g. via a beam delivery system BD. The illumination system IL may include various types of optical components, such as refractive, reflective, magnetic, electromagnetic, electrostatic, and/or other types of optical components, or any combination thereof, for directing, shaping, and/or controlling radiation. The illuminator IL may be used to condition the radiation beam B to have a desired spatial and angular intensity distribution in its cross section at a plane of the patterning device MA.

The term “projection system” PS used herein should be broadly interpreted as encompassing various types of projection system, including refractive, reflective, catadioptric, anamorphic, magnetic, electromagnetic and/or electrostatic optical systems, or any combination thereof, as appropriate for the exposure radiation being used, and/or for other factors such as the use of an immersion liquid or the use of a vacuum. Any use of the term “projection lens” herein may be considered as synonymous with the more general term “projection system” PS.

The lithographic apparatus LA may be of a type wherein at least a portion of the substrate may be covered by a liquid having a relatively high refractive index, e.g., water, so as to fill a space between the projection system PS and the substrate W—which is also referred to as immersion lithography. More information on immersion techniques is given in U.S. Pat. No. 6,952,253, which is incorporated herein by reference.

The lithographic apparatus LA may also be of a type having two or more substrate supports WT (also named “dual stage”). In such “multiple stage” machine, the substrate supports WT may be used in parallel, and/or steps in preparation of a subsequent exposure of the substrate W may be carried out on the substrate W located on one of the substrate support WT while another substrate W on the other substrate support WT is being used for exposing a pattern on the other substrate W.

In addition to the substrate support WT, the lithographic apparatus LA may comprise a measurement stage. The measurement stage is arranged to hold a sensor and/or a cleaning device. The sensor may be arranged to measure a property of the projection system PS or a property of the radiation beam B. The measurement stage may hold multiple sensors. The cleaning device may be arranged to clean part of the lithographic apparatus, for example a part of the projection system PS or a part of a system that provides the immersion liquid. The measurement stage may move beneath the projection system PS when the substrate support WT is away from the projection system PS.

In operation, the radiation beam B is incident on the patterning device, e.g. mask, MA which is held on the mask support MT, and is patterned by the pattern (design layout) present on patterning device MA. Having traversed the mask MA, the radiation beam B passes through the projection system PS, which focuses the beam onto a target portion C of the substrate W. With the aid of the second positioner PW and a position measurement system IF, the substrate support WT can be moved accurately, e.g., so as to position different target portions C in the path of the radiation beam B at a focused and aligned position. Similarly, the first positioner PM and possibly another position sensor (which is not explicitly depicted in FIG. 1) may be used to accurately position the patterning device MA with respect to the path of the radiation beam B. Patterning device MA and substrate W may be aligned using mask alignment marks M1, M2 and substrate alignment marks P1, P2. Although the substrate alignment marks P1, P2 as illustrated occupy dedicated target portions, they may be located in spaces between target portions. Substrate alignment marks P1, P2 are known as scribe-lane alignment marks when these are located between the target portions C.

As shown in FIG. 2 the lithographic apparatus LA may form part of a lithographic cell LC, also sometimes referred to as a lithocell or (litho)cluster, which often also includes apparatus to perform pre- and post-exposure processes on a substrate W. Conventionally these include spin coaters SC to deposit resist layers, developers DE to develop exposed resist, chill plates CH and bake plates BK, e.g. for conditioning the temperature of substrates W e.g. for conditioning solvents in the resist layers. A substrate handler, or robot, RO picks up substrates W from input/output ports I/O1, I/O2, moves them between the different process apparatus and delivers the substrates W to the loading bay LB of the lithographic apparatus LA. The devices in the lithocell, which are often also collectively referred to as the track, are typically under the control of a track control unit TCU that in itself may be controlled by a supervisory control system SCS, which may also control the lithographic apparatus LA, e.g. via lithography control unit LACU.

In order for the substrates W exposed by the lithographic apparatus LA to be exposed correctly and consistently, it is desirable to inspect substrates to measure properties of patterned structures, such as overlay errors between subsequent layers, line thicknesses, critical dimensions (CD), etc. For this purpose, inspection tools (not shown) may be included in the lithocell LC. If errors are detected, adjustments, for example, may be made to exposures of subsequent substrates or to other processing steps that are to be performed on the substrates W, especially if the inspection is done before other substrates W of the same batch or lot are still to be exposed or processed.

An inspection apparatus, which may also be referred to as a metrology apparatus, is used to determine properties of the substrates W, and in particular, how properties of different substrates W vary or how properties associated with different layers of the same substrate W vary from layer to layer. The inspection apparatus may alternatively be constructed to identify defects on the substrate W and may, for example, be part of the lithocell LC, or may be integrated into the lithographic apparatus LA, or may even be a stand-alone device. The inspection apparatus may measure the properties on a latent image (image in a resist layer after the exposure), or on a semi-latent image (image in a resist layer after a post-exposure bake step PEB), or on a developed resist image (in which the exposed or unexposed parts of the resist have been removed), or even on an etched image (after a pattern transfer step such as etching).

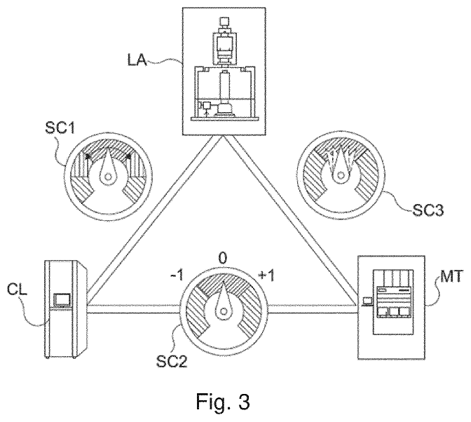

Typically, the patterning process in a lithographic apparatus LA is one of the most critical steps in the processing which requires high accuracy of dimensioning and placement of structures on the substrate W. To ensure this high accuracy, three systems may be combined in a so called “holistic” control environment as schematically depicted in FIG. 3. One of these systems is the lithographic apparatus LA which is (virtually) connected to a metrology tool MT (a second system) and to a computer system CL (a third system). The key of such “holistic” environment is to optimize the cooperation between these three systems to enhance the overall process window and provide tight control loops to ensure that the patterning performed by the lithographic apparatus LA stays within a process window. The process window defines a range of process parameters (e.g. dose, focus, overlay) within which a specific manufacturing process yields a defined result (e.g. a functional semiconductor device)—typically within which the process parameters in the lithographic process or patterning process are allowed to vary.

The computer system CL may use (part of) the design layout to be patterned to predict which resolution enhancement techniques to use and to perform computational lithography simulations and calculations to determine which mask layout and lithographic apparatus settings achieve the largest overall process window of the patterning process (depicted in FIG. 3 by the double arrow in the first scale SC1). Typically, the resolution enhancement techniques are arranged to match the patterning possibilities of the lithographic apparatus LA. The computer system CL may also be used to detect where within the process window the lithographic apparatus LA is currently operating (e.g. using input from the metrology tool MT) to predict whether defects may be present due to e.g. sub-optimal processing (depicted in FIG. 3 by the arrow pointing “0” in the second scale SC2).

The metrology tool MT may provide input to the computer system CL to enable accurate simulations and predictions, and may provide feedback to the lithographic apparatus LA to identify possible drifts, e.g. in a calibration status of the lithographic apparatus LA (depicted in FIG. 3 by the multiple arrows in the third scale SC3).

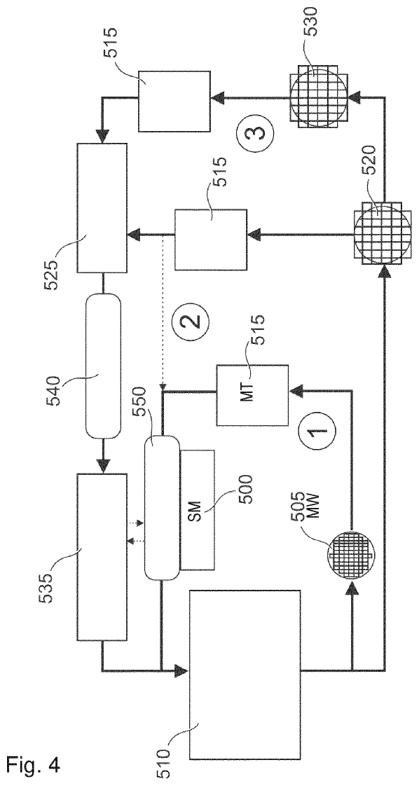

FIG. 4 depicts the overall lithography and metrology method incorporating a stability module 500 (essentially an application running on a server, in this example). Shown are three main process control loops, labeled 1, 2, 3.

The first loop provides calibration of the lithographic apparatus for stability control of the lithography apparatus using the stability module 500 and reference substrates (reference wafers) provided with reference features. A reference wafer (MW) 505 is shown being passed from a lithography cell 510, having been exposed by a lithographic apparatus within the lithography cell 510 to form patterned features in proximity to the reference features. By measuring overlay error, using the metrology tool (MT) 515, between the patterned and reference features, deviations in performance of the lithographic apparatus can be measured. The determined overlay error enables determination of calibration parameters used in accurate positioning of subsequent substrates or patterns provided by the lithographic apparatus.

Typically these calibration parameters are based on applying a model (for example comprising polynomial base functions defined across the substrate) to the measurement data to obtain model parameters used to describe a grid of the lithographic tool. The grid definition is used in positioning the substrate such that patterns are provided at correct positions on the wafers. The calibration parameters may be calculated by the stability module (SM) 500 so as to provide feedback 550, which is passed to the lithography apparatus within lithography cell 510, and used when performing further exposures to pattern production wafers.

The second (APC) loop is for local scanner control on-product (determining focus, dose, and overlay on product wafers). The exposed product wafer 520 is passed to metrology unit 515 where information relating for example to parameters such as critical dimension, sidewall angles and overlay is determined and passed onto the Advanced Process Control (APC) module 525. This data is also passed to the stability module 500. Process corrections 540 are made before the Manufacturing Execution System (MES) 535 takes over, providing control of the lithography apparatus, in communication with the stability module 500.

The third control loop is to allow metrology integration into the second (APC) loop (e.g., for double patterning). The post etched wafer 530 is passed to metrology unit 515 which again measures parameters such as critical dimensions, sidewall angles and overlay, read from the wafer. These parameters are passed to the Advanced Process Control (APC) module 525. The loop continues the same as with the second loop.

The subject of the invention as described in this document relates to the first loop; calibration of the lithographic apparatus based on periodic measurement on reference substrates which are provided with reference features. As stated before the periodic measurements are normally overlay measurements which are recorded as a wafer map comprising a grid of overlay measurements (which may be represented as overlay residuals). The reference features are etched in the reference substrate and the patterned features are provided in close proximity to the reference features, for example in a photoresist layer on top of the reference features. Often the reference features are configured as bottom gratings of an overlay mark and the patterned features are configured as the top grating of said overlay mark. The overlay mark as such is then composed of two gratings on top of each other. The overlay measurements are performed by the metrology tool 515 and relate to the relative position of the patterned features with respect to the reference features. A properly calibrated lithographic apparatus would have positioned the patterned features at a correct position relative to its corresponding reference features. In case the positioning (sub)systems of the lithographic apparatus have drifted the overlay measurements would pick up a change in overlay between the patterned and reference features. The measured overlay errors are subsequently used to (re-)calibrate the positioning systems of the lithographic apparatus by correcting its internal grid used in controlling the substrate position and/or image positioning systems (such as controllers of the projection lens).

During the alignment (measurement) and the patterning step by the lithographic apparatus the reference substrate is clamped to the substrate table (also commonly referred to as substrate holder) of said lithographic apparatus. The substrate table conventionally has a plurality of burls to support the substrate. The total area of the burls that contacts the substrate is normally small compared to the total area of a substrate.

It is important that the clamping as such does not significantly deform the reference substrate as this may lead to induced overlay errors which are not attributable to any drift of systems within the lithographic apparatus. In particular deformations which are in the plane of the substrate and are not uniform or radially symmetric may cause relatively large calibration errors as they: i) cannot be easily corrected by the alignment system as there are normally too few alignment marks present to accurately capture non-uniform or asymmetric deformations, and ii) cannot be modelled by low order polynomials. Modelling of the measured overlay data is needed to derive parameters for calibration of the lithographic apparatus. The necessity to use higher order polynomials will almost certainly lead to less efficient noise suppression and a higher risk of introducing high frequent components in the modelled data which are not actually associated with any drift mechanisms within the lithographic apparatus. Hence the occurrence of asymmetric and/or non-uniform in-plane deformations of the reference substrate should be avoided.

The mechanism behind clamping induced in-plane deformation (IPD) of a substrate is related to the loading process. First the substrate is supported by so-called e-pins which hold it at three positions Therefore, the weight of the substrate causes it to distort and it is desirable that this distortion be released before exposures. On the other hand, it is desirable that the substrate be held very firmly during exposure. There are two reasons for this. Firstly, the substrate is subjected to very large accelerations during an exposure sequence in order to achieve a high throughput and must not move on the substrate holder. Secondly, the substrate absorbs energy from the projection beam during exposure and therefore heats up locally. Such local heating can cause thermal expansion causing slip between substrate and burls leading to overlay errors. By holding the substrate firmly to the substrate holder such distortion can be resisted.

Two clamping techniques are commonly used. In vacuum-clamping a pressure differential across the substrate is established, e.g., by connecting the space between the substrate holder and the substrate to an under-pressure that is lower than a higher pressure above the substrate. The pressure difference gives rise to a force holding the substrate to the substrate holder. In electrostatic clamping, electrostatic forces are used to exert a force between the substrate and the substrate holder. Several different arrangements are known to achieve this. In one arrangement a first electrode is provided on the lower surface of the substrate and a second electrode on the upper surface (also referred to as the clamp surface) of the substrate holder. A potential difference is established between the first and second electrodes. In another arrangement two semi-circular electrodes are provided on the substrate holder and a conductive layer is provided on the substrate. A potential difference is applied between the two semi-circular electrodes so that the two semi-circular electrodes and the conductive layer on the substrate act like two capacitors in series.

It is commonly observed that clamping of a flat or non-flat (curved) substrate results in substrate deformation. This is caused by friction forces, occurring between the substrate and the substrate holder, preventing a stress-free flattening of the substrate when it is placed on the clamp surface of the substrate holder. These forces are directed within the plane of the substrate and result in significant compressive and/or tensile stress components. By elastic deformation these stress components cause translation of features on the substrate which result in significantly worse overlay performance of the lithographic apparatus. The friction forces need however to be sufficiently large to keep the substrate firmly attached to the substrate holder during the lithographic process.

Hence it is normally unavoidable that any measured overlay error has some contribution due to above explained clamping induced IPD. It is proposed to reduce the impact of said clamping induced IPD for a substrate used in calibration of a lithographic apparatus by selecting a material of the substrate that has a stiffness (expressed by its Young's modulus) which is substantially invariant to the orientation of the axis along which the Young's modulus is defined. For product substrates the choice of material is normally given by requirements related to the semiconductor material needed for proper functioning of devices built on the substrate (using a variety of processes such as a lithographic process, deposition process and etching processes). However for a (reference) substrate solely used for calibration purposes there are less stringent constraints on the material choice. A good example of a suitable material for said reference substrate could be crystalline silicon having a (111) orientation of its crystal axis.

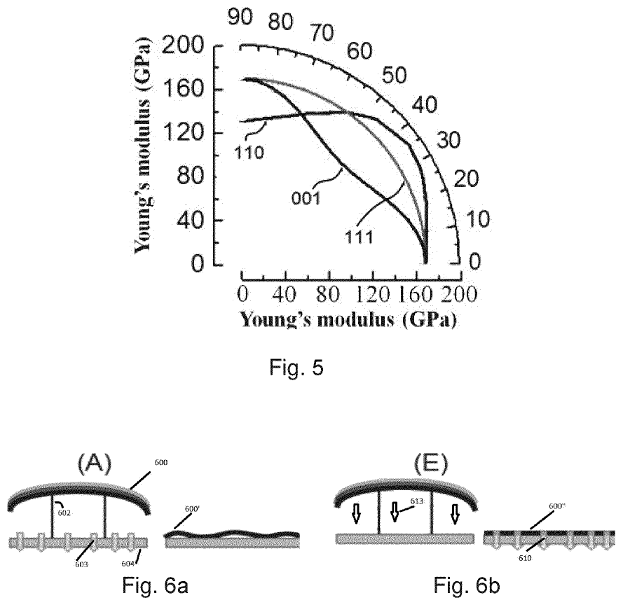

FIG. 5 illustrates the value of Young's modulus along an axis within a plane of the substrate having an angle between 0 and 90 degrees. It is clear that Young's modulus of (111) silicon does not depend on the orientation of the axis along which Young's modulus is defined. This is in contrast to typical materials used for state of the art reference substrates and most product substrates, such as silicon (110) and silicon (001) which demonstrate a large dependency of its Young's modulus regarding the orientation (angle) of said axis, and hence the orientation of the substrate with respect to the substrate holder (its angular orientation as for example indicated by determining the position of a notch of the substrate). In addition to said invariant behaviour (111) silicon is otherwise comparable to other crystalline silicon varieties used for said state of the art reference substrates and production substrates. The latter meaning that adoption of (111) silicon reference substrates will not lead to unforeseen issues for example relating to a difference in mechanical and surface properties (such as thermal behaviour, roughness of its backside, friction forces, etc.).

The effect of selecting (111) silicon, or any other suitable material having an angularly invariant Young's modulus, is that clamping forces will yield more symmetric and uniform deformation profiles across the substrate. As mentioned, asymmetric and non-uniform IPD profiles will pose problems as they are more difficult to correct and need higher order models to be characterized.

To verify whether a (111) silicon substrate indeed gives a more favourable clamping induced overlay contribution (due to IPD) the experiment as depicted in FIGS. 6a and 6b has been performed. FIG. 6a depicts a regular clamping sequence (A). The (curved) substrate 600 is initially held by e-pins 602 of the substrate holder 604 (two black lines supporting the substrate) and a strong clamping force (indicated by the multiple arrows 603 within the substrate table) is introduced to provide a quick and firmly clamped substrate, as depicted in the figure to the right; the substrate has no time to settle and friction forces between the burls and the backside of the substrate are expected to introduce a large amount of IPD as indicated by the wrinkled surface 600′ of the substrate after clamping. FIG. 6b depicts an alternative clamping sequence (E) which is during normal production and calibration exposures not preferred as this sequence takes a considerable time to be executed. The substrate is again held by the e-pins 602, but now a slow descent 613 of the e-pins (no clamping force present) is used to allow the curved substrates to settle. During the descent 613 of the substrate an air cushion is formed. Once the reference substrate is in full contact with the burls and is settled the clamping force 610 is introduced to prepare for patterning of the reference substrate. As there was no clamping force acting on the reference substrate during its descent there we were no significant friction forces present which may have introduced a clamping related IPD contribution. As a result the surface of the substrate 600″ is relatively undistorted and flat.

To determine the contribution of the clamping induced IPD to overlay error in case of following the regular clamping sequence a reference substrate was patterned by the lithographic apparatus twice, once subject to the regular clamping sequence and once subject to clamping sequence (E). After each individual patterning step the overlay error between the patterned and reference features was measured. The difference in measured overlay between the first patterning step associated with the regular clamping sequence and the second patterning step associated with the alternative clamping sequence was attributed to the clamping induced overlay error. By following this procedure for both regular silicon (110) reference substrates and the proposed improved (111) silicon reference substrates it can be determined whether indeed the (111) silicon reference substrates give less pronounced asymmetric and/or non-uniform clamping induced overlay error contributions.

In preparation to the above mentioned procedure first the newly proposed (111) reference substrates needed to be manufactured. In view of the deviating orientation of (111) silicon's crystal axis (which is not perpendicular to the normal of its surface) a process of Reactive Ion Etching (RIE) was chosen to provide etched reference features to the (111) silicon reference substrate. RIE based etching was chosen as it is expected to also work well for materials in which for example chemical etching based methods would yield non-perpendicularly etched features (as chemical etchants normally travel along a crystal axis of the to be etched material).

To verify geometric integrity of RIE based reference features both a (110) and a (111) silicon substrate were provided with reference features. The position errors of the reference features were determined by the alignment system of a lithographic apparatus for 8 different wavelengths. The variation in determined position error across the 8 wavelengths is indicative of the amount of geometric deformation (relative to a nominal rectangularly shaped feature).

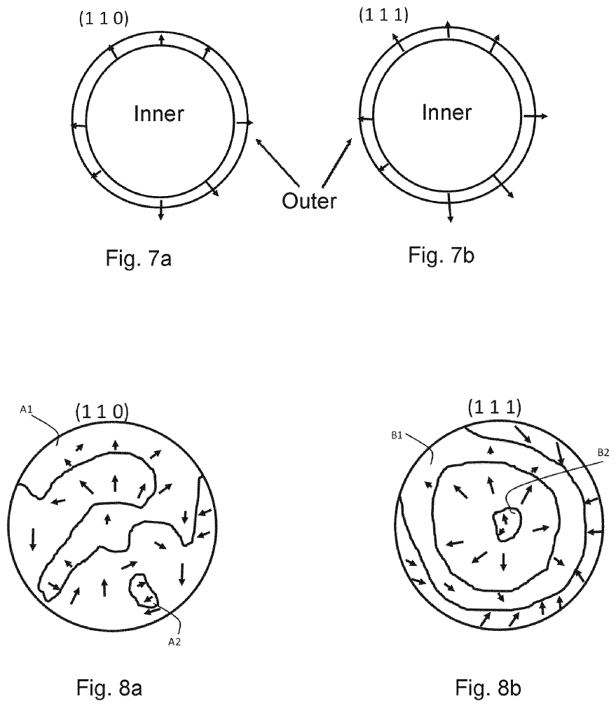

FIG. 7a illustrates the observed through wavelength position variation. It was found that the inner region of the state of the art (110 silicon) reference substrate did not demonstrate a significant feature deformation, while the outer region close to the edge of the substrate indicated a significant tilt (slant) of the feature was likely to be present.

FIG. 7b illustrates that also the new (111 silicon) reference substrate has an almost identical fingerprint of the across wavelength feature position variation as the state of the art reference substrate. Hence it was concluded that the RIE based reference features on the (111) silicon reference substrate were not of a significantly lower geometric quality when compared to reference features on state of the art reference substrates, which gave confidence that overlay measurements can be directly compared between state of the art and new (111) silicon reference substrates.

The procedure as explained in FIGS. 6a and 6b and accompanying text was used to derive for both a (110) and a (111) silicon substrate the contribution of the clamping induced IPD to the overlay fingerprint.

FIG. 8a demonstrates that for a state of the art (110) reference substrate the clamping induced overlay errors (depicted by the black arrows) are quite small in some areas A1 and A2 while for some areas the overlay error was significantly larger. From FIG. 8a it can be concluded that the clamping induced overlay error is highly asymmetric and not very uniform for the state of the art reference substrate.

FIG. 8b demonstrates that for a new (111) reference substrate the clamping induced overlay errors are distributed much more in a radial symmetric pattern as the areas B1 and B2 of low observed clamping induced overlay error are almost oriented in a concentric constellation. Hence it can be concluded that the use of (111) silicon reference substrates will reduce impact of the clamping induced contribution to the overlay error as the pattern of FIG. 8b is more easily modelled by a lower order model (less high frequent components) and more easily correctable as the fingerprint is more similar to simple scaling deformation.

Instead of using a (111) silicon reference substrate also the use of other materials may be considered, such as amorphous silicon, glass like materials, metals or ceramic materials. Typically these materials also have an angularly invariant Young's modulus and hence are expected to equally be of use for manufacturing of reference substrates that give a reduced impact of clamping induced IPD. However silicon (111) may be preferred as it shares many properties with state of the art reference substrates and most widely used production wafers.

Existing methods of calibrating lithographic apparatuses are improved by using reference substrates according to embodiments of the invention. In an embodiment the method comprises at least the following steps:
a) obtaining a substrate provided with reference features and having a Young's modulus which is substantially invariant to the orientation of an axis within the plane of the substrate along which said Young's modulus is defined;
b) clamping the substrate to a substrate table of the lithographic apparatus;
c) providing patterned features to the clamped substrate using said lithographic apparatus, each patterned feature being provided in proximity to a corresponding reference feature;
d) measuring the position of each patterned feature relative to its corresponding reference feature; and
e) calibrating a grid associated with positioning of substrates by the lithographic apparatus based on the measured positions of the patterned features.

In an embodiment the substrate is a wafer made from silicon having a (1 1 1) crystal direction.

In an embodiments the substrate is a wafer made from an amorphous material, such as amorphous silicon, a glass, a metal or a ceramic material.

In an embodiment the reference features have been provided by a process of Reactive Ion Etching (RIE) to the substrate.

In an embodiment the patterned features are formed in a photosensitive layer provided to the substrate.

In an embodiment the positions of the patterned features relative to the reference features are measured by an overlay measurement apparatus.

In an embodiment the method further comprises modelling of the measured positions to obtain fingerprint of the measured positions across the substrate.

The model used may be chosen to comprise only lower order polynomial base functions, for example limited to 3^{rd} order across the surface of the (reference) substrate. This would substantially suppress measurement noise and since the clamping induced IPD of the improved reference substrate does not give rise to large non-uniform and asymmetric components the accuracy of the calibration parameters derived from the model is not compromised.

In an embodiment the model consists of polynomial base functions describing at most 3^{rd} order behaviour across the substrate.

In an embodiment a method of providing reference features to a substrate for calibration of a lithographic apparatus is provided, the method comprising; obtaining a substrate made from (1 1 1) oriented silicon; and using a process of Reactive Ion Etching (RIE) to provide said reference features to the substrate.

In an embodiment a substrate for calibration of a lithographic apparatus is provided, characterized in that the substrate has a Young's modulus which is substantially invariant to the orientation of an axis within the plane of the substrate along which said Young's modulus is defined.

In an embodiment the substrate is a wafer made from crystalline silicon having a (1 1 1) orientation.

In an embodiment the substrate is made from an amorphous material, such as amorphous silicon, a glass, a metal or a ceramic material.

In an embodiment the substrate further comprises reference features provided by a process of Reactive Ion Etching (RIE) to the substrate.

In an embodiment the reference features are configured as bottom gratings of a composed overlay mark.

In an embodiment the patterned features are configured as top gratings of a composed overlay mark.

Although specific reference may be made in this text to the use of lithographic apparatus in the manufacture of ICs, it should be understood that the lithographic apparatus described herein may have other applications. Possible other applications include the manufacture of integrated optical systems, guidance and detection patterns for magnetic domain memories, flat-panel displays, liquid-crystal displays (LCDs), thin-film magnetic heads, etc.

Although specific reference may be made in this text to embodiments of the invention in the context of an inspection or metrology apparatus, embodiments of the invention may be used in other apparatus. Embodiments of the invention may form part of a mask inspection apparatus, a lithographic apparatus, or any apparatus that measures or processes an object such as a wafer (or other substrate) or mask (or other patterning device). It is also to be noted that the term metrology apparatus or metrology system encompasses or may be substituted with the term inspection apparatus or inspection system. A metrology or inspection apparatus as disclosed herein may be used to detect defects on or within a substrate and/or defects of structures on a substrate. In such an embodiment, a characteristic of the structure on the substrate may relate to defects in the structure, the absence of a specific part of the structure, or the presence of an unwanted structure on the substrate, for example.

Although specific reference is made to “metrology apparatus/tool/system” or “inspection apparatus/tool/system”, these terms may refer to the same or similar types of tools, apparatuses or systems. E.g. the inspection or metrology apparatus that comprises an embodiment of the invention may be used to determine characteristics of physical systems such as structures on a substrate or on a wafer. E.g. the inspection apparatus or metrology apparatus that comprises an embodiment of the invention may be used to detect defects of a substrate or defects of structures on a substrate or on a wafer. In such an embodiment, a characteristic of a physical structure may relate to defects in the structure, the absence of a specific part of the structure, or the presence of an unwanted structure on the substrate or on the wafer.

Although specific reference may have been made above to the use of embodiments of the invention in the context of optical lithography, it will be appreciated that the invention, where the context allows, is not limited to optical lithography and may be used in other applications, for example imprint lithography.

While specific embodiments of the invention have been described above, it will be appreciated that the invention may be practiced otherwise than as described. The descriptions above are intended to be illustrative, not limiting. Thus, it will be apparent to one skilled in the art that modifications may be made to the invention as described without departing from the scope of the claims set out below.

1. A method comprising:
obtaining a substrate provided with reference features;
clamping the substrate to a substrate table of a lithographic apparatus;
providing patterned features to the clamped substrate using the lithographic apparatus, each patterned feature being provided in proximity to a corresponding reference feature;
measuring the position of each patterned feature relative to its corresponding reference feature; and
calibrating a grid associated with positioning of substrates by the lithographic apparatus based on the measured positions of the patterned features, wherein the substrate has a Young's modulus which is substantially invariant to the orientation of an axis within the plane of the substrate along which the Young's modulus is defined.

2. The method of claim 1, wherein the substrate is a wafer made from silicon having a (1 1 1) crystal direction.

3. The method of claim 1, wherein the substrate is a wafer made from an amorphous material, a glass, a metal or a ceramic material.

4. The method of claim 2, wherein the reference features have been provided by a process of Reactive lon Etching (RIE) to the substrate.

5. The method of claim 1, wherein the patterned features are formed in a photosensitive layer provided to the substrate.

6. The method of claim 1, wherein the positions of the patterned features relative to the reference features are measured by an overlay measurement apparatus.

7. The method of claim 1, further comprising modelling of the measured positions to obtain a fingerprint of the measured positions across the substrate.

8. The method of claim 7, wherein polynomial base functions of the model describe at most 3^{rd} order behaviour across the substrate.

9. A method of providing reference features to a substrate for calibration of a lithographic apparatus according to the method of claim 1, the method comprising:
obtaining a substrate made from (1 1 1) oriented silicon; and
using a process of Reactive lon Etching (RIE) to provide the reference features to the substrate.

10. A substrate configured to be used in performing the method of claim 1.

11. The substrate of claim 10, wherein the substrate is a wafer made from crystalline silicon having a (1 1 1) orientation.

12. The substrate of claim 10, wherein the substrate is made from an amorphous material, a glass, a metal or a ceramic material.

13. The substrate of claim 11, further comprising reference features provided by a process of Reactive lon Etching (RIE) to the substrate.

14. The substrate of claim 10, wherein the reference features are configured as bottom gratings of a composed overlay mark.

15. The substrate of claim 14, further comprising patterned features within a photoresist layer provided to the surface of the substrate and wherein the patterned features are configured as top gratings of a composed overlay mark.

16. The method of claim 1, wherein the reference features are configured as bottom gratings of a composed overlay mark.

17. The method of claim 16, further comprising patterned features within a photoresist layer provided to the surface of the substrate and wherein the patterned features are configured as top gratings of a composed overlay mark.

18. The method of claim 9, wherein patterned features are formed in a photosensitive layer provided to the substrate.

19. The method of claim 18, wherein the reference features are configured as bottom gratings of a composed overlay mark.

20. The method of claim 19, wherein the patterned features are configured as top gratings of a composed overlay mark.
